(19) United States
(12) Patent Application Publication
(10) Pub. No.: US 2026/0074695 A1
(43) Pub. Date: Mar. 12, 2026

(54) ANALOG CIRCUIT

(71) Applicant: REALTEK SEMICONDUCTOR CORPORATION, HSINCHU (TW)

(72) Inventors: Yun-Tse Chen, Hsinchu (TW); Yang-Fu Pan, Hsinchu (TW); Chia-Wei Yen, Hsinchu (TW)

(21) Appl. No.: 19/320,749

(22) Filed: Sep. 5, 2025

(30) Foreign Application Priority Data
Sep. 12, 2024 (TW) 113134734

(51) Int. Cl. H03K 19/003; H03K 19/017; H03K 19/0185; H03K 19/0948; H03K 19/21

(52) U.S. Cl. CPC H03K 19/00361; H03K 19/01707; H03K 19/018521; H03K 19/0948; H03K 19/215

(57) ABSTRACT

An analog circuit includes a logic output circuit and a standard cell. The logic output circuit outputs a first power supply voltage or a low-level signal to be an output signal. The standard cell includes at least two first-type transistors and at least two second-type transistors. The first-type transistors are connected in series. The first-type transistors receive a second power supply voltage, and output the second power supply voltage according to the output signal. A first voltage value of the first power supply voltage is less than a second voltage value of the second power supply voltage. The second-type transistors are connected in parallel, coupled to the first-type transistors at an output terminal, and output the low-level signal according to the output signal. First types of the first-type transistors are different from second types of the second-type transistors.

### BACKGROUND OF THE INVENTION

### 1. Field of the Invention

The present disclosure relates to an analog circuit, especially to an analog circuit capable of preventing leakage current.

### 2. Description of Related Art

A digital circuit can be composed of standard cells. The standard cell can be composed of logic gates, such as NAND gates, NOR gates, D-flip-flops, latches, and so on. With advancements in manufacturing processes, standard cells have become smaller and faster, thereby reducing the area and power consumption of digital circuits and making digital circuits more advantageous.

Analog circuits also require the use of logic gates. If standard cells can be widely used in analog circuits, the analog circuits can similarly gain advantages. However, when standard cells are applied to analog circuits, signal transmission across different voltage domains in the analog circuits may result in voltage differences that cause poor transistor switching control, thereby generating leakage current.

### SUMMARY OF THE INVENTION

In some aspects, an object of the present disclosure is to, but not limited to, provides an analog circuit that makes an improvement to the prior art.

An embodiment of an analog circuit of the present disclosure includes a logic output circuit and a standard cell. The logic output circuit is configured to receive a first power supply voltage, and output the first power supply voltage or a low-level signal to be an output signal according to a control voltage. The standard cell includes at least two first-type transistors and at least two second-type transistors. The at least two first-type transistors are connected to each other in series, and coupled to an output terminal of the standard cell. The at least two first-type transistors are configured to receive a second power supply voltage, and output the second power supply voltage through the output terminal according to the output signal. A first voltage value of the first power supply voltage is less than a second voltage value of the second power supply voltage. The at least two second-type transistors are connected to each other in parallel, coupled to the at least two first-type transistors at the output terminal, and output the low-level signal through the output terminal according to the output signal. First types of the at least two first-type transistors are different from second types of the at least two second-type transistors.

Technical features of some embodiments of the present disclosure make an improvement to the prior art. The analog circuit of the present disclosure adopts standard cells and arranges the standard cells in a specific configuration to prevent the generation of leakage current caused by poor transistor switching control due to voltage differences during signal transmission across different voltage domains in the analog circuit.

These and other objectives of the present invention will no doubt become obvious to those of ordinary skill in the art after reading the following detailed description of the preferred embodiments that are illustrated in the various figures and drawings.

### BRIEF DESCRIPTION OF THE DRAWINGS

FIG. 1 shows an embodiment of an analog circuit of the present disclosure.

FIG. 2 shows an embodiment of an analog circuit of the present disclosure.

FIG. 3 shows an embodiment of an analog circuit of the present disclosure.

### DETAILED DESCRIPTION OF THE PREFERRED EMBODIMENTS

To address the issue of leakage current in analog circuits of the prior art, the present disclosure provides an improved analog circuit, which will be described in detail as shown below.

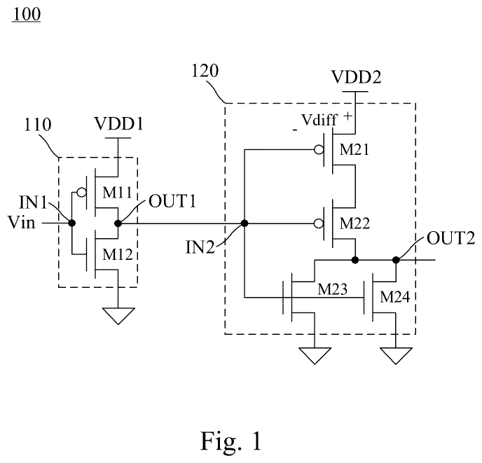

FIG. 1 shows an embodiment of an analog circuit 100 of the present disclosure. As shown in the figure, the analog circuit 100 includes a logic output circuit 110 and a standard cell 120. In some embodiments, the standard cell 120 may be a standard cell used in digital circuits. The standard cell 120 may be composed of logic gates, such as a NAND gate, a NOR gate, a D-flip-flop, a latch, and so on. With advancements in manufacturing processes, the standard cell 120 has become smaller and faster. To further reduce the area and enhance the speed of the analog circuit 100 of the present disclosure, the analog circuit 100 may also adopt the standard cell 120.

The logic output circuit 110 is configured to receive a first power supply voltage VDD1, and the logic output circuit 110 is configured to output the first power supply voltage VDD1 or a low-level signal (e.g., a ground signal) as an output signal according to the control of the control voltage Vin. In some embodiments, the logic output circuit 110 may be, but is not limited to, an inverting circuit.

The standard cell 120 includes at least two first-type transistors (e.g., transistors M21 and M22) and at least two second-type transistors (e.g., transistors M23 and M24). In some embodiments, the standard cell 120 may be, but is not limited to, a NOR gate.

As shown in the figure, the at least two first-type transistors (e.g., transistors M21 and M22) on the high-voltage side of the standard cell 120 are connected to each other in series and coupled to an output terminal OUT2 of the standard cell 120. The at least two first-type transistors (e.g., transistors M21 and M22) are configured to receive a second power supply voltage VDD2, and the at least two first-type transistors are configured to output the second power supply voltage VDD2 through the output terminal OUT2 according to the control of the output signal of the logic output circuit 110. A first voltage value of the first power supply voltage VDD1 is less than a second voltage value of the second power supply voltage VDD2.

In addition, the at least two second-type transistors (e.g., transistors M23 and M24) are connected to each other in parallel. The at least two second-type transistors (e.g., transistors M23 and M24) are coupled to the at least two first-type transistors (e.g., transistors M21 and M22) at the output terminal OUT2, and the at least two second-type transistors are configured to output a low-level signal (e.g., a ground signal) through the output terminal OUT2 according to the control of the output signal of the logic output circuit 110.

Furthermore, the first types of the at least two first-type transistors (e.g., transistors M21 and M22) are different from the second types of the at least two second-type transistors (e.g., transistors M23 and M24). In some embodiments, the first types of the at least two first-type transistors (e.g., transistors M21 and M22) may be P-type. In other words, the first-type transistors may be P-type metal-oxide-semiconductor field-effect transistors (MOSFET). Additionally, the second types of the at least two second-type transistors (e.g., transistors M23 and M24) may be N-type. In other words, the second-type transistors may be N-type metal-oxide-semiconductor field-effect transistors.

For example, assuming that the first voltage value of the first power supply voltage VDD1 is 0.9V (volts) and the second voltage value of the second power supply voltage VDD2 is 1.0V, the logic output circuit 110 outputs the first power supply voltage VDD1 of 0.9V to the transistor M21. In addition, the transistor M21 receives the second power supply voltage VDD2 of 1.0V. As a result, there is a voltage difference Vdiff of 0.1V across the transistor M21. In this case, if the standard cell 120 includes only a single transistor M21, the single transistor M21 may generate a leakage current due to the voltage difference Vdiff of 0.1V.

To address this problem, the standard cell 120 of the present disclosure is designed to include serially connected transistors M21 and M22 on the high-voltage side. The effective length of the serially connected transistors M21 and M22 is increased. Therefore, even if a voltage difference Vdiff is caused by different voltage domains across the logic output circuit 110 and the standard cell 120, the serially connected transistors M21 and M22 still do not generate leakage current, thereby avoiding additional power consumption.

In some embodiments, the standard cell 120 further includes an input terminal IN2. The input terminal IN2 is coupled to the logic output circuit 110 and is configured to receive the output signal of the logic output circuit 110. In addition, a plurality of control terminals (e.g., gate terminals) of the at least two first-type transistors (e.g., transistors M21 and M22) and the at least two second-type transistors (e.g., transistors M23 and M24) are coupled to the input terminal IN2. Therefore, the standard cell 120 can be equivalent to an inverting circuit.

In some embodiments, the at least two first-type transistors include a first transistor M21 and a second transistor M22. The first transistor M21 includes a first terminal, a control terminal, and a second terminal. The first terminal (e.g., the upper terminal) of the first transistor M21 is configured to receive the second power supply voltage VDD2. The control terminal (e.g., the gate terminal) of the first transistor M21 is configured to receive the output signal of the logic output circuit 110 through the input terminal IN2. In addition, the second transistor M22 includes a first terminal, a control terminal, and a second terminal. The first terminal (e.g., the upper terminal) of the second transistor M22 is coupled to the second terminal (e.g., the lower terminal) of the first transistor M21. The control terminal (e.g., the gate terminal) of the second transistor M22 is configured to receive the output signal of the logic output circuit 110 through the input terminal IN2. The second terminal (e.g., the lower terminal) of the second transistor M22 is coupled to the output terminal OUT2.

In some embodiments, the at least two second-type transistors include a third transistor M23 and a fourth transistor M24. The third transistor M23 includes a first terminal, a control terminal, and a second terminal. The first terminal (e.g., the upper terminal) of the third transistor M23 is coupled to the output terminal OUT2. The control terminal (e.g., the gate terminal) of the third transistor M23 is configured to receive the output signal of the logic output circuit 110 through the input terminal IN2. The second terminal (e.g., the lower terminal) of the third transistor M23 is coupled to a low-level terminal (e.g., a ground terminal). In addition, the fourth transistor M24 includes a first terminal, a control terminal, and a second terminal. The first terminal (e.g., the upper terminal) of the fourth transistor M24 is coupled to the output terminal OUT2. The control terminal (e.g., the gate terminal) of the fourth transistor M24 is configured to receive the output signal of the logic output circuit 110 through the input terminal IN2. The second terminal (e.g., the lower terminal) of the fourth transistor M24 is coupled to the low-level terminal (e.g., a ground terminal).

In some embodiments, the logic output circuit 110 includes an input terminal IN1, an output terminal OUT1, a first transistor M11, and a second transistor M12. The input terminal IN1 is configured to receive the control voltage Vin. The first transistor M11 includes a first terminal, a control terminal, and a second terminal. The first terminal (e.g., the upper terminal) of the first transistor M11 is configured to receive the first power supply voltage VDD1. The control terminal (e.g., the gate terminal) of the first transistor M11 is configured to receive the control voltage Vin through the input terminal IN1. The second terminal (e.g., the lower terminal) of the first transistor M11 is coupled to the output terminal OUT1. In addition, the second transistor M12 includes a first terminal, a control terminal, and a second terminal. The first terminal (e.g., the upper terminal) of the second transistor M12 is coupled to the output terminal OUT1. The control terminal (e.g., the gate terminal) of the second transistor M12 is configured to receive the control voltage Vin through the input terminal IN1. The second terminal (e.g., the lower terminal) of the second transistor M12 is coupled to the low-level terminal (e.g., the ground terminal).

In some embodiments, the logic output circuit 110 may output the first power supply voltage VDD1 or output a low-level signal (e.g., a ground signal) to the standard cell 120 according to the control of the control voltage Vin. Subsequently, the standard cell 120 may output the second power supply voltage VDD2 or output the low-level signal (e.g., the ground signal) according to the output signal of the logic output circuit 110.

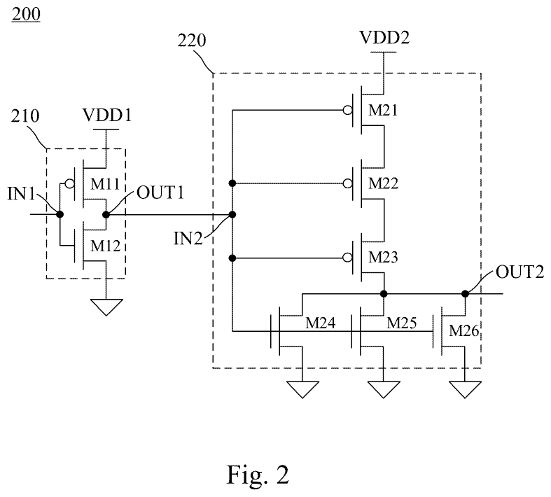

FIG. 2 shows an embodiment of an analog circuit 200 of the present disclosure. As shown in the figure, the analog circuit 200 includes a logic output circuit 210 and a standard cell 220. Compared with the analog circuit 100 in FIG. 1, the configuration of the standard cell 220 in FIG. 2 is different. As shown in FIG. 2, the standard cell 220 includes three first-type transistors (e.g., transistors M21˜M23) and three second-type transistors (e.g., transistors M24˜M26). Compared with the standard cell 120 in FIG. 1, the standard cell 220 in FIG. 2 has more first-type transistors (e.g., transistors M21˜M23) connected in series on the high-voltage side, resulting in a greater equivalent length of the series-connected first-type transistors (e.g., transistors M21˜M23). Therefore, the standard cell 220 is less likely to generate leakage current, thereby further reducing additional power consumption.

Referring to FIG. 2, the at least two first-type transistors include a first transistor M21, a second transistor M22, and a third transistor M23. The first transistor M21 includes a first terminal, a control terminal, and a second terminal. The first terminal (e.g., the upper terminal) of the first transistor M21 is configured to receive a second power supply voltage VDD2. The control terminal (e.g., the gate terminal) of the first transistor M21 is configured to receive an output signal of the logic output circuit 210 through an input terminal IN2. In addition, the second transistor M22 includes a first terminal, a control terminal, and a second terminal. The first terminal (e.g., the upper terminal) of the second transistor M22 is coupled to the second terminal (e.g., the lower terminal) of the first transistor M21. The control terminal (e.g., the gate terminal) of the second transistor M22 is configured to receive the output signal of the logic output circuit 210 through the input terminal IN2. Besides, the third transistor M23 includes a first terminal, a control terminal, and a second terminal. The first terminal (e.g., the upper terminal) of the third transistor M23 is coupled to the second terminal (e.g., the lower terminal) of the second transistor M22. The control terminal (e.g., the gate terminal) of the third transistor M23 is configured to receive the output signal of the logic output circuit 210 through the input terminal IN2. The second terminal (e.g., the lower terminal) of the third transistor M23 is coupled to an output terminal OUT2.

Referring to FIG. 2, the at least two second-type transistors include a fourth transistor M24, a fifth transistor M25, and a sixth transistor M26. The fourth transistor M24 includes a first terminal, a control terminal, and a second terminal. The first terminal (e.g., the upper terminal) of the fourth transistor M24 is coupled to the output terminal OUT2. The control terminal (e.g., the gate terminal) of the fourth transistor M24 is configured to receive the output signal of the logic output circuit 210 through the input terminal IN2. The second terminal (e.g., the lower terminal) of the fourth transistor M24 is coupled to a low-level terminal (e.g., a ground terminal). The fifth transistor M25 includes a first terminal, a control terminal, and a second terminal. The first terminal (e.g., the upper terminal) of the fifth transistor M25 is coupled to the output terminal OUT2. The control terminal (e.g., the gate terminal) of the fifth transistor M25 is configured to receive the output signal of the logic output circuit 210 through the input terminal IN2. The second terminal (e.g., the lower terminal) of the fifth transistor M25 is coupled to the low-level terminal (e.g., the ground terminal). The sixth transistor M26 includes a first terminal, a control terminal, and a second terminal. The first terminal (e.g., the upper terminal) of the sixth transistor M26 is coupled to the output terminal OUT2. The control terminal (e.g., the gate terminal) of the sixth transistor M26 is configured to receive the output signal of the logic output circuit 210 through the input terminal IN2. The second terminal (e.g., the lower terminal) of the sixth transistor M26 is coupled to the low-level terminal (e.g., the ground terminal).

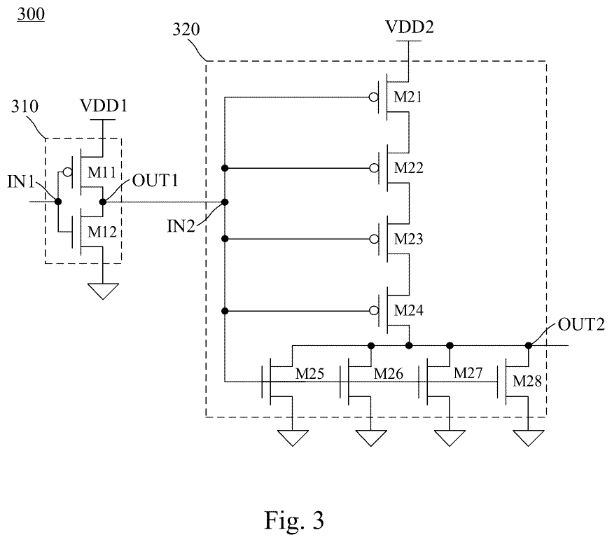

FIG. 3 shows an embodiment of an analog circuit 300 of the present disclosure. As shown in the figure, the analog circuit 300 includes a logic output circuit 310 and a standard cell 320. Compared with the analog circuit 200 of FIG. 2, the configuration of the standard cell 320 of the analog circuit 300 of FIG. 3 is different. As shown in FIG. 3, the standard cell 320 includes four first-type transistors (e.g., transistors M21 to M24) and four second-type transistors (e.g., transistors M25˜M28). Compared with the standard cell 220 of FIG. 2, the standard cell 320 of FIG. 3 has more first-type transistors (e.g., transistors M21˜M24) connected in series on the high-voltage side, and the equivalent length of the series-connected first-type transistors (e.g., transistors M21˜M24) is greater. Therefore, the standard cell 320 is less likely to generate leakage current, thereby further avoiding additional power consumption.

It should be noted that the coupling manner of each component in the analog circuit 300 of FIG. 3 is similar to the coupling manner of each component in the analog circuit 100 of FIG. 1 and the analog circuit 200 of FIG. 2. The related description regarding the analog circuit 300 is omitted herein for brevity. In addition, the present disclosure is not limited to the embodiments shown in FIG. 2 and FIG. 3, which are merely configured to illustratively describe one of the implementations of the present disclosure. In other embodiments, the high-voltage side of the standard cells 220 and 320 may include other suitable numbers of transistors, such as five transistors, six transistors, and so on, depending on actual requirements.

It should be noted that the present disclosure is not limited to the embodiments as shown in FIG. 1 to FIG. 3, they are merely examples for illustrating the implements of the present disclosure, and the scope of the present disclosure shall be defined based on the claims as shown below. In view of the foregoing, it is intended that the present disclosure covers modifications and variations to the embodiments of the present disclosure, and modifications and variations to the embodiments of the present disclosure also fall within the scope of the following claims and their equivalents.

As described above, technical features of some embodiments of the present disclosure make an improvement to the prior art. The analog circuit of the present disclosure adopts standard cells and arranges the standard cells in a specific configuration to prevent the generation of leakage current caused by poor transistor switching control due to voltage differences during signal transmission across different voltage domains in the analog circuit.

It is noted that people having ordinary skill in the art can selectively use some or all of the features of any embodiment in this specification or selectively use some or all of the features of multiple embodiments in this specification to implement the present invention as long as such implementation is practicable; in other words, the way to implement the present invention can be flexible based on the present disclosure.

The descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. An analog circuit, comprising:
a logic output circuit, configured to receive a first power supply voltage, and output the first power supply voltage or a low-level signal to be an output signal according to a control voltage; and
a standard cell, comprising:
at least two first-type transistors, connected to each other in series, and coupled to an output terminal of the standard cell, wherein the at least two first-type transistors are configured to receive a second power supply voltage, and output the second power supply voltage through the output terminal according to the output signal, wherein a first voltage value of the first power supply voltage is less than a second voltage value of the second power supply voltage; and
at least two second-type transistors, connected to each other in parallel, coupled to the at least two first-type transistors at the output terminal, and output the low-level signal through the output terminal according to the output signal, wherein first types of the at least two first-type transistors are different from second types of the at least two second-type transistors.

2. The analog circuit of claim 1, wherein the standard cell further comprises:
an input terminal, configured to receive the output signal;
wherein a plurality of control terminals of the at least two first-type transistors and the at least two second-type transistors are coupled to the input terminal.

3. The analog circuit of claim 2, wherein the at least two first-type transistors comprise:
a first transistor, comprising:
a first terminal, configured to receive the second power supply voltage;
a control terminal, configured to receive the output signal through the input terminal; and
a second terminal; and
a second transistor, comprising:
a first terminal, coupled to the second terminal of the first transistor;
a control terminal, configured to receive the output signal through the input terminal; and
a second terminal, coupled to the output terminal.

4. The analog circuit of claim 3, wherein the at least two second-type transistors comprise:
a third transistor, comprising:
a first terminal, coupled to the output terminal;
a control terminal, configured to receive the output signal through the input terminal; and
a second terminal, coupled to a low-level terminal; and
a fourth transistor, comprising:
a first terminal, coupled to the output terminal;
a control terminal, configured to receive the output signal through the input terminal; and
a second terminal, coupled to the low-level terminal.

5. The analog circuit of claim 2, wherein the at least two first-type transistors comprise:
a first transistor, comprising:
a first terminal, configured to receive the second power supply voltage;
a control terminal, configured to receive the output signal through the input terminal; and
a second terminal;
a second transistor, comprising:
a first terminal, coupled to the second terminal of the first transistor;
a control terminal, configured to receive the output signal through the input terminal; and
a second terminal; and
a third transistor, comprising:
a first terminal, coupled to the second terminal of the second transistor;
a control terminal, configured to receive the output signal through the input terminal; and
a second terminal, coupled to the output terminal.

6. The analog circuit of claim 5, wherein the at least two second-type transistors comprise:
a fourth transistor, comprising:
a first terminal, coupled to the output terminal;
a control terminal, configured to receive the output signal through the input terminal; and
a second terminal, coupled to a low-level terminal;
a fifth transistor, comprising:
a first terminal, coupled to the output terminal;
a control terminal, configured to receive the output signal through the input terminal; and
a second terminal, coupled to the low-level terminal; and
a sixth transistor, comprising:
a first terminal, coupled to the output terminal;
a control terminal, configured to receive the output signal through the input terminal; and
a second terminal, coupled to the low-level terminal.

7. The analog circuit of claim 1, wherein the logic output circuit comprises:
an input terminal, configured to receive the control voltage;
an output terminal, configured to output the output signal;
a first transistor, comprising:
a first terminal, configured to receive the first power supply voltage;
a control terminal, configured to receive the control voltage through the input terminal; and
a second terminal, coupled to the output terminal; and
a second transistor, comprising:
a first terminal, coupled to the output terminal;
a control terminal, configured to receive the control voltage through the input terminal; and
a second terminal, coupled to a low-level terminal.

8. The analog circuit of claim 1, wherein the logic output circuit comprises an inverting circuit.

9. The analog circuit of claim 1, wherein the standard cell comprises a NOR gate.

10. The analog circuit of claim 1, wherein the first types of the at least two first-type transistors comprise P-type, and the second types of the at least two second-type transistor comprise N-type.
